(19) United States
(12) Patent Application Publication
(10) Pub. No.: US 2023/0056921 A1
(43) Pub. Date: Feb. 23, 2023

(54) MEMORY AND MANUFACTURING METHOD THEREOF

(71) Applicant: CHANGXIN MEMORY TECHNOLOGIES, INC., Hefei City, Anhui (CN)

(72) Inventor: Chun-Sheng JUAN LU, Hefei City, Anhui (CN)

(21) Appl. No.: 17/442,280

(22) PCT Filed: Jun. 17, 2021
(86) PCT No.: PCT/CN2021/100737

§ 371 Date: Sep. 23, 2021

(30) Foreign Application Priority Data
Nov. 5, 2020 (CN) 202011221712.8

(51) Int. Cl. H01L 27/108

(52) U.S. Cl. CPC H01L 27/10888; H01L 27/10814; H01L 27/10823; H01L 27/10885

(57) ABSTRACT

The present application provides a memory and a manufacturing method thereof, and relates to the field of semiconductor technologies. The memory includes a substrate, the substrate is provided with a control region, and two sides of the control region are respectively provided with storage regions; each of the storage regions includes multiple rows of first active regions, and all the first contact regions in each row of the first active regions are connected by a bit line; the control region includes multiple second active regions, each of the second active regions is provided with a first gate and a first source/drain region and a second source/drain region that are located on two sides of the first gate, and all the first gates in the control region are connected with each other to form a control line; the first source/drain region and the second source/drain region in a same second active region are respectively connected with a corresponding bit line. The memory in the present application controls, through control lines, whether the bit line connected with the first source/drain region and the bit line connected with the second source/drain region are connected, so as to control the time of each read operation and write operation. In this way, the storage speed of the memory is increased and the performance of the memory is improved.

### CROSS-REFERENCE TO RELATED APPLICATIONS

The present application claims the priority to Chinese Patent Application No. 202011221712.8, titled “MEMORY AND MANUFACTURING METHOD THEREOF”, filed to the China National Intellectual Property Administration (CNIPA) on Nov. 5, 2020, which is incorporated herein by reference in its entirety.

### TECHNICAL FIELD

The present application relates to the technical field of semiconductors, and in particular, to a memory and a manufacturing method thereof.

### BACKGROUND

The dynamic random access memory (DRAM) is a semiconductor memory that randomly writes and reads data at high speed, and is widely used in data storage devices or apparatuses.

The DRAM generally includes multiple memory cells, which are arranged in rows and columns to form a memory matrix. The memory cells in each column are connected by a word line (WL), and the memory cells in each row are connected by a bit line (BL). During reading or writing, an entire column of memory cells connected by a WL is selected by column, and then an entire row of memory cells connected by a BL is selected by row. In this way, when a BL and a WL of a target memory cell are both selected, the target memory cell is selected, and data can be read from or written into the target memory cell.

However, when the target memory cell is selected, the read or write cycle of the DRAM is relatively long and the speed is slow, which is not conducive to improving the performance of the DRAM.

### SUMMARY

In view of the foregoing problems, embodiments of the present application provide a memory and a manufacturing method thereof, to increase the speed of the memory and thereby improve the performance of the memory.

To achieve the foregoing objectives, the embodiments of the present application provide the following technical solutions:

A first aspect of the embodiments of the present application provides a memory. The memory includes a substrate, the substrate is provided with a control region, and two sides of the control region are respectively provided with storage regions; each of the storage regions includes multiple first active regions, the multiple first active regions are arranged in multiple rows along a first direction, each of the first active regions is provided with a first contact region, and all the first contact regions in each row of the first active regions are connected by a bit line; the control region includes multiple second active regions that are arranged along the first direction and that are in a one-to-one correspondence with the multiple rows formed by the first active regions; each of the second active regions is provided with a first gate and a first source/drain region and a second source/drain region that are located on two sides of the first gate, and all the first gates in the control region are connected with each other to form a control line; and the first source/drain region and the second source/drain region in a same second active region are respectively connected with a corresponding bit line, and the bit line connected with the first source/drain region and the bit line connected with the second source/drain region are located on two sides of the control line.

In some implementations, a first conductive portion is provided on the first source/drain region in each of the second active regions, and the first source/drain region is connected with the corresponding bit line through the first conductive portion.

In some implementations, a second conductive portion is provided on the second source/drain region in each of the second active regions, and the second source/drain regions is connected with the corresponding bit line through the second conductive portion.

In some implementations, the first conductive portion and the second conductive portion are located on a same layer.

In some implementations, a third conductive portion is provided on each of the first contact regions; and in each row of the first active regions in each of the storage regions, the third conductive portion on each of the first contact regions is connected to one of the bit lines.

In some implementations, the first conductive portion, the second conductive portion, and the third conductive portion are located on a same layer.

In some implementations, the multiple first active regions in each of the storage regions are arranged in multiple columns along a second direction; in any two adjacent rows of the first active regions, columns of all the first active regions in one row and columns of all the first active regions in the other row are alternately arranged; each of the first active regions in a same column intersects two word lines; in any two adjacent columns of the first active regions, ends of the first active regions in one column and ends of the first active regions in the other column that are close to each other intersect a same word line, where the second direction is perpendicular to the first direction; and each of the first active regions in a same column is provided with two second gates, and the two second gates are respectively connected with two word lines alternately arranged in the first active region.

In some implementations, the first contact region in each of the first active regions is located between the two second gates.

In some implementations, the first gate and the second gate are located on a same layer.

In some implementations, each of the first active regions further includes a second contact region provided on a side of each of the second gates away from the first contact region, and each of the second contact regions is connected with a corresponding charge storage element.

In some implementations, multiple control regions and multiple storage regions are provided on the substrate, and the control regions and the storage regions are alternately arranged.

A second aspect of the embodiments of the present application provides a manufacturing method of a memory, including:

providing a substrate;

forming a control region on the substrate and forming storage regions on both sides of the control region, where each of the storage regions includes multiple first active regions, the multiple first active regions are arranged in multiple rows along a first direction, and the control region includes multiple second active regions that are arranged along the first direction and that are in a one-to-one correspondence with the multiple rows formed by the first active regions;

forming a first contact region in each of the first active regions, and providing, in each of the second active regions, a first gate and a first source/drain region and a second source/drain region that are located on two sides of the first gate, where all the first gates in the control region are connected with each other to form a control line; and

forming a bit line connecting all first contact regions in each row of the first active regions, where the first source/drain region and the second source/drain region in a same second active region are respectively connected with a corresponding bit line, and the bit line connected with the first source/drain region and the bit line connected with the second source/drain region are located on two sides of the control line.

In some implementations, a first conductive portion is formed on the first source/drain region in each of the second active regions, and the first source/drain region is connected with the corresponding bit line through the first conductive portion.

In some implementations, a second conductive portion is formed on the second source/drain region in each of the second active regions, and the second source/drain region is connected with the corresponding bit line through the second conductive portion.

In some implementations, the first conductive portion and the second conductive portion are formed in a same process step.

In some implementations, a third conductive portion is formed on each of the first contact regions; and in each row of the first active regions in each of the storage regions, the third conductive portion on each of the first contact regions is connected with one of the bit lines.

In some implementations, the first conductive portion, the second conductive portion, and the third conductive portion are formed in a same process step.

In some implementations, the multiple first active regions in each of the storage regions are arranged in multiple columns along a second direction; in any two adjacent rows of the first active regions, columns of all the first active regions in one row and columns of all the first active regions in the other row are alternately arranged; each of the first active regions in a same column intersects two same word lines; in any two adjacent columns of the first active regions, ends of the first active regions in one column and ends of the first active regions in the other column that are close to each other are connected with a same word line; each of the first active regions in a same column is provided with two second gates, and the two second gates are respectively connected with two word lines alternately arranged in the first active region.

In some implementations, the first contact region in each of the first active regions is located between the two second gates.

In some implementations, the first gate and the second gate are provided in a same process step.

In some implementations, a second contact region is further formed in each of the first active regions on a side of each of the second gates away from the first contact region, and each of the second contact regions is connected with a corresponding charge storage element.

In some implementations, multiple control regions and multiple storage regions are formed on the substrate, and the control regions and the storage regions are alternately arranged.

In the memory provided in the embodiments of the present application, the control region is provided on the substrate, two sides of the control region are respectively provided with the storage regions, the first contact regions in each row of the first active regions in each of the storage regions are connected by one bit line, and the first source/drain region and the second source/drain region of each of the second active regions in the control region are respectively connected with the corresponding bit line on both sides of the second active region. In this way, the voltage of the control line can be controlled to control whether the bit line connected with the first source/drain region and the bit line connected with the second source/drain region are connected. Further, an effective length of the bit line is controlled during each read operation and write operation. To be specific, the number of memory cells connected to the effective bit line is controlled during each read operation and write operation. In this way, the time of each read operation and write operation is controlled, so that the average storage speed of the memory is increased and the performance of the memory is improved.

According to the manufacturing method of a memory in the embodiments of the present application, the manufactured memory has a fast storage speed and excellent performance, and the manufacturing process is simple with low difficulty.

The present application provides a memory and a manufacturing method thereof. The present application describes the technical problems resolved by the embodiments of the present application, the technical features constituting the technical solutions and the beneficial effects brought about by the technical features of these technical solutions. In addition, other technical problems to be resolved by the embodiments of the present application, other technical features included in the technical solutions and beneficial effects brought about by these technical features will be described in further detail in the detailed description.

### BRIEF DESCRIPTION OF THE DRAWINGS

To describe the technical solutions in the embodiments of the present application or in the prior art more clearly, the following briefly describes the accompanying drawings required for describing the embodiments or the prior art. Apparently, the accompanying drawings in the following description show some embodiments of the present application, and a person of ordinary skill in the art may still derive other drawings from these accompanying drawings without creative efforts.

FIG. 1 is a schematic diagram of the principle of a memory in the related art;

FIG. 2a is a schematic structural diagram of first active regions and second active regions provided on a substrate according to an embodiment;

FIG. 2b is a cross-sectional view along AA in FIG. 2a;

FIG. 3a is a schematic structural diagram of a memory in which WLs and control lines are formed according to an embodiment;

FIG. 3b is a cross-sectional view along BB in FIG. 3a;

FIG. 4a is a first schematic structural diagram of a memory in which BLs are formed according to an embodiment;

FIG. 4b is a cross-sectional view along CC in FIG. 4a;

FIG. 4c is a second schematic structural diagram of a memory in which BLs are formed according to an embodiment;

FIG. 4d is a cross-sectional view along DD in FIG. 4d;

FIG. 5a is a schematic structural diagram a memory in which capacitors are formed according to an embodiment;

FIG. 5b is a cross-sectional view along EE in FIG. 5a;

FIG. 5c is a cross-sectional view along FF in FIG. 5a;

FIG. 6 is a schematic diagram of the principle of a memory according to an embodiment; and

FIG. 7 is a flowchart of a manufacturing method of a memory according to an embodiment.

### REFERENCE NUMERALS

100: memory cell; 101: buffer region; 200: substrate; 201: control region; 202: storage region; 203: first active region; 204: first contact region; 205: BL; 206: WL; 207: groove insulation portion; 208: second gate; 209: gate oxide layer; 210: gate barrier layer; 211: gate conductive layer; 212: second contact region; 213: fourth conductive portion; 214: capacitor; 215: second active region; 216: first gate; 217: first source/drain region; 218: second source/drain region; 219: control line; 220: gate insulation layer; 221: first conductive portion; 222: second conductive portion; 223: third conductive portion.

### DETAILED DESCRIPTION

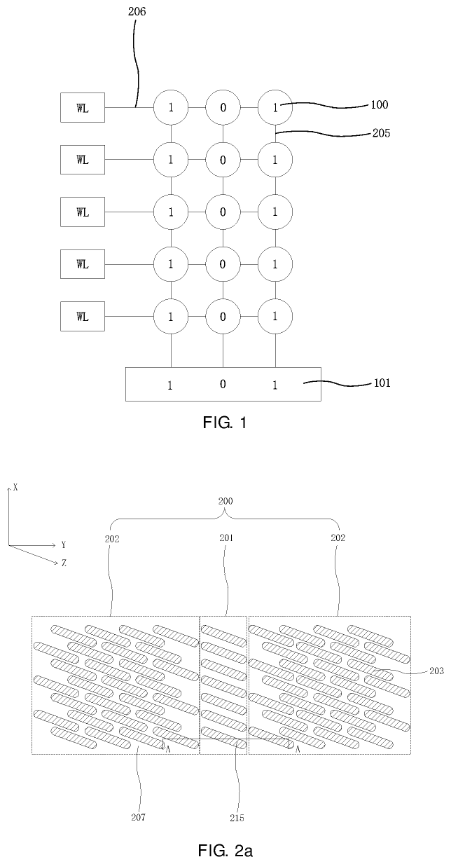

In the related art, a memory generally includes multiple memory cells 100. For example, as shown in FIG. 1, the memory includes 15 memory cells 100, forming a memory matrix with five rows and three columns. Memory cells 100 in each row are connected by a word line 206, and memory cells 100 in each column are connected by a bit line 205. The principle of a read operation on the memory is as follows:

For example, the read operation is to be performed on the memory cell 100 in the first column of the first row. First, all memory cells 100 in the first row are selected through the WL 206 connecting them, and are temporarily stored in a buffer region 101. Then, all memory cells 100 in the first column are selected through the BL 205 connecting them. In this way, the memory cell 100 in the first column and the first row can be selected, and then the read operation can be performed.

However, the inventor of the present application found that, for example, when the memory cell 100 in the first column and the first row needs to be selected, the memory cell 100 in the first column and the second row, the memory cell 100 in the first column and the third row, the memory cell 100 in the first column and the fourth row and the memory cell 100 in the first column and the fifth row are also selected, but loading of the memory cell 100 in the first column and the second row, the memory cell 100 in the first column and the third row, the memory cell 100 in the first column and the fourth row and the memory cell 100 in the first column and the fifth row is unnecessary. Consequently, the entire loading time is longer, the storage speed of the memory is lower, and the performance of the memory deteriorates.

To this end, the present application provides a memory and a manufacturing method thereof. A control region and storage regions located on both sides of the control region are provided on a substrate. Multiple rows of first active regions are provided in each storage region, and each row of first active regions are connected by a BL. Multiple second active regions are provided in the control region, and each second active region is provided with a first gate and a first source/drain region and a second source/drain region that are located on two sides of the first gate, respectively. The first source/drain region and the second source/drain region are respectively connected with BLs on both sides of the second active region. In this way, the voltage of the first gate can be controlled to control whether all first active regions in a corresponding row in two neighboring storage regions are connected through the BL connected with the first source/drain region and the BL connected with the second source/drain region. Further, an effective length of the BL is controlled during each read operation and write operation. To be specific, the number of memory cells connected to an effective BL is controlled during each read operation and write operation. In this way, the time of each read operation and write operation is reduced, so that the average storage speed of the memory is increased and the performance of the memory is improved.

To make the above objectives, features, and advantages of the embodiments of the present application clearer, the technical solutions in the embodiments of the present application are clearly and completely described below with reference to the accompanying drawings in the embodiments of the present application. Apparently, the described embodiments are some rather than all of the embodiments of the present application. All other embodiments obtained by a person of ordinary skill in the art based on the embodiments of the present application without creative efforts shall fall within the protection scope of the present application.

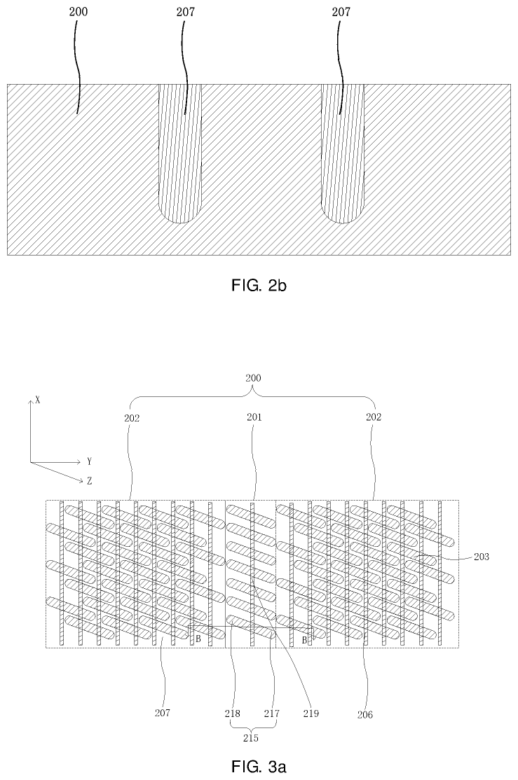

As shown in FIG. 2a, a memory provided in an embodiment includes a substrate 200, the substrate 200 is provided with a control region 201, and two sides of the control region 201 are respectively provided with storage regions 202.

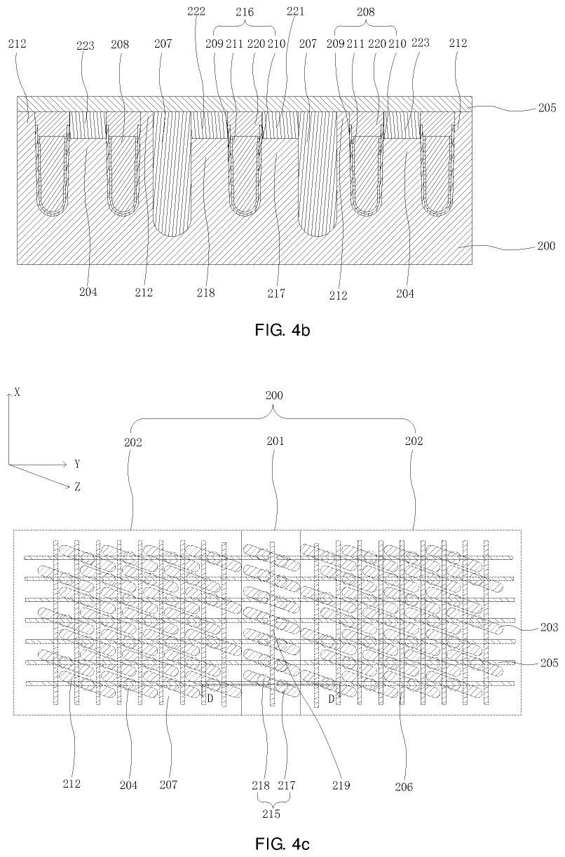

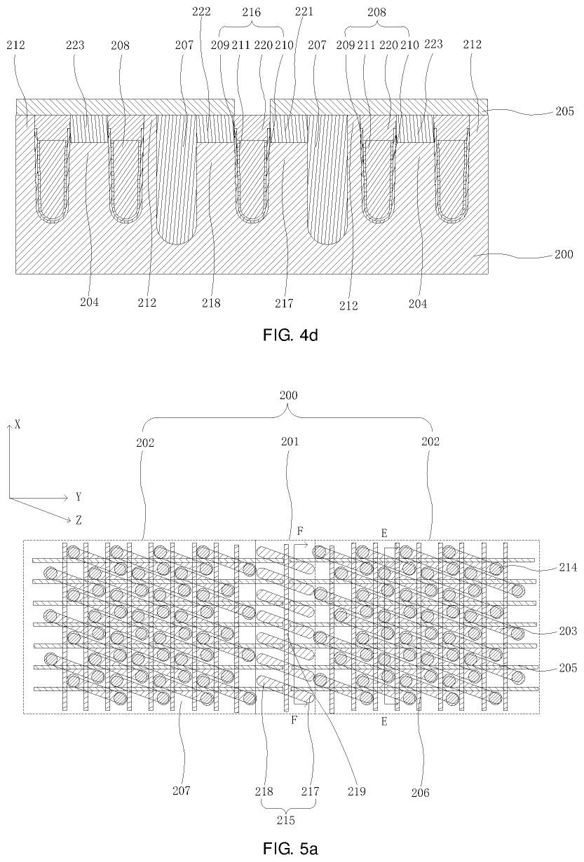

Referring to FIG. 2a, each storage region 202 includes multiple first active regions 203, and the multiple first active regions 203 are arranged in multiple rows along a first direction. For example, in this embodiment, the multiple first active regions 203 are arranged in seven rows along the first direction, and each row includes four first active regions 203. The first direction may be the X direction shown in FIG. 2a. Referring to FIG. 4b, each first active region 203 is provided with a first contact region 204. In this embodiment, the first contact region 204 is approximately located in the middle of the first active region 203, and all first contact regions 204 in each row of first active regions 203 are connected by a BL 205.

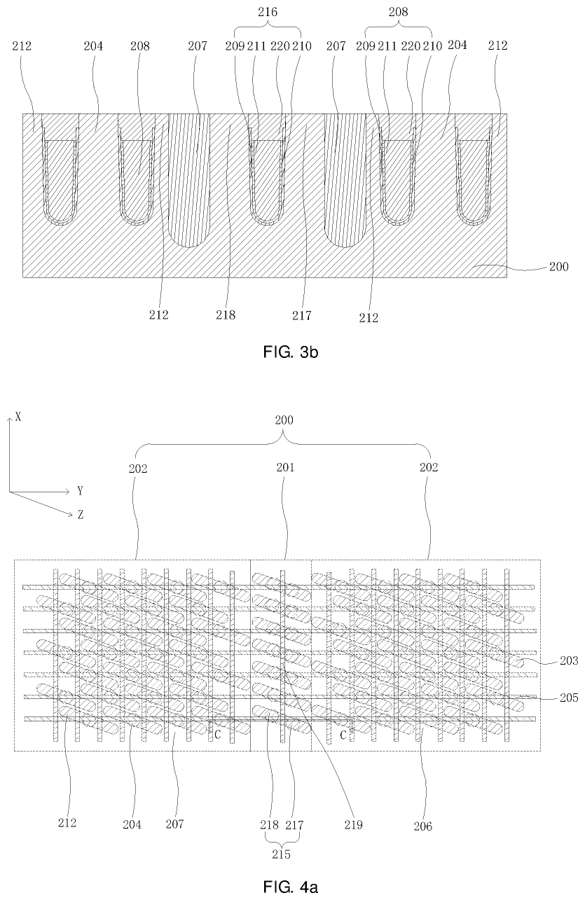

Referring to FIG. 2a and FIG. 3a, in each storage region 202, the multiple first active regions 203 are also arranged in multiple columns along a second direction, and the second direction is perpendicular to the first direction. The second direction may be the Y direction shown in FIG. 3a. In any two adjacent rows of first active regions 203, all first active regions 203 in one row are alternately arranged with all first active regions 203 in the other row, and each first active region in a same column 203 intersects two WLs 206. In any two adjacent columns of first active regions 203, ends of the first active regions in one column and ends of the first active regions in the other column that are close to each other intersect a same WL 206. Further, the first active region 203 has a strip structure extending along a third direction. The third direction and the second direction are arranged at a predetermined angle, and the angle ranges from 15° to 30°. The third direction is the Z direction shown in FIG. 3a.

It should be noted that, as shown in FIG. 2a and FIG. 2b, groove insulation portions 207 are provided between adjacent first active regions 203. Grooves between adjacent first active regions 203 are filled with insulation materials to form the groove insulation portions 207, groove insulation portions 207are used to electrically isolate the adjacent first active regions 203.

Referring to FIG. 3a and FIG. 3b, each first active region 203 in a same column is provided with two second gates 208, and the two second gates 208 are respectively connected with two WLs 206 arranged alternately in the first active region 203. Each second gate 208 includes, for example, a gate oxide layer 209, a gate barrier layer 210 and a gate conductive layer 211. Specifically, a first gate groove is provided on the first active region 203, the gate oxide layer 209 is deposited on an inner surface of the first gate groove, the gate barrier layer 210 is deposited on an inner surface of the gate oxide layer 209, and a groove in the gate barrier layer 210 is filled with the gate conductive layer 211. The gate oxide layer is made of a high dielectric constant material or an oxide. The gate barrier layer 210 may be, for example, a metal electrode material for preventing the gate oxide layer 209 from being mixed with the gate conductive layer 211. The gate conductive layer 211 is made of, for example, a metal electrode material. In addition, a groove insulation portion 207 provided between adjacent first active regions 203 in a same column is further provided with a WL groove, a conductive material electrically connected to the gate conductive layer 211 is deposited in the WL groove, and the conductive material in the WL groove is electrically connected with the gate conductive layer 211, to form the WL 206.

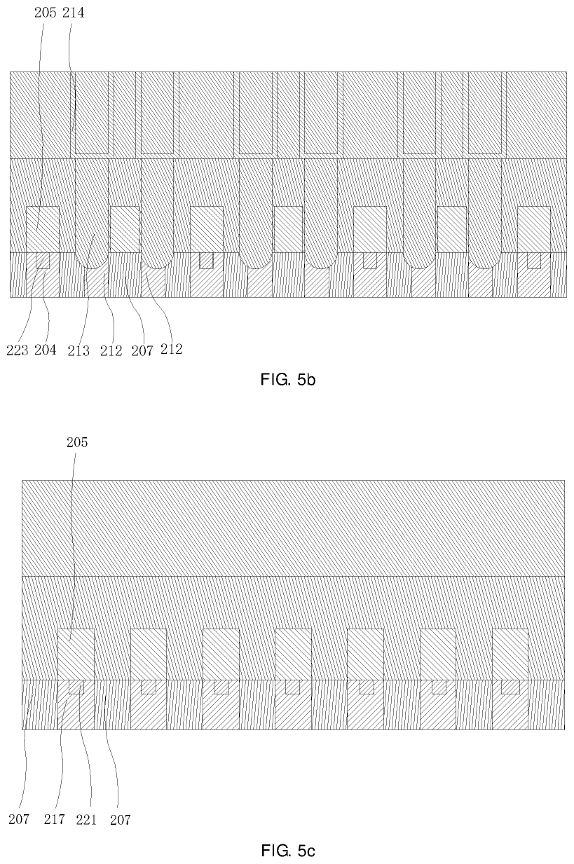

Referring to FIG. 3b, in some implementations, each first active region 203 further includes a second contact region 212 disposed on a side of each second gate 208 away from the first contact region 204, and each second contact region 212 is connected with a corresponding charge storage element. The charge storage element is, for example, a capacitor 214 shown in FIG. 5a. For example, the capacitor 214 is connected with the second contact region 212 through a fourth conductive portion 213 shown in FIG. 5b. Referring to FIG. 3b, the first contact region 204 in each first active region 203 is located between two second gates 208. In this case, each first active region 203 is connected with one BL 205, and connected with two WLs 206. In this way, the two second gates 208, the first contact region 204 and the two second contact regions 212 in each first active region 203 jointly form two metal oxide semiconductor (MOS) field effect transistors, where one second gate 208, a second contact region 212 on one side of the second gate 208, and a first contact region 204 on the other side of the second gate 208 jointly form one MOS field effect transistor. This arrangement allows the memory a more compact structure with higher integration.

Referring to FIG. 4a, in the memory of this embodiment, each control region 201 includes multiple second active regions 215 that are arranged along the first direction and that are in a one-to-one correspondence with the multiple rows formed by the first active regions 203. The second active region 215 also has a strip structure extending along the third direction. The third direction and the second direction are arranged at a predetermined angle, and the angle ranges from 15° to 30°. It should be noted that groove insulation portions 207 are also provided between the second active regions 215, and between the second active region 215 and the first active region 203. The groove insulation portions 207 are also used to electrically isolate two adjacent second active regions 215, and the adjacent first active region 203 and the second active region 215.

Referring to FIG. 4a and FIG. 4b, each second active region 215 is provided with a first gate 216 and a first source/drain region 217 and a second source/drain region 218 that are located on two sides of the first gate216, respectively. Each control region 201 includes a control line 219 passing through all second active regions 215, which is formed by connecting all first gates 216.

Still referring to FIG. 4b, the first gate 216 includes a gate oxide layer 209, a gate barrier layer 210 and a gate conductive layer 211. Specifically, a second gate groove is formed in the second active region 215. The gate oxide layer 209 is deposited on an inner surface of the second gate groove, the gate barrier layer 210 is deposited on an inner surface of the gate oxide layer 209, and a groove formed in the gate barrier layer 210 is filled with the gate conductive layer 211. The gate oxide layer 209 is made of a high dielectric constant material or an oxide. The gate barrier layer 210 may be, for example, a metal electrode material for preventing the gate oxide layer 209 from being mixed with the gate conductive layer 211. The gate conductive layer 211 is made of, for example, a metal electrode material. The selection and combination of the materials on all the layers of the first gate 216 may be defined according to an actual needed work function.

For example, in some implementations, a control line groove is provided in a groove insulation portion 207 in the control region 201, and the control line groove in the groove insulation portion 207 in the control region 201 is connected with the second gate groove in the second active region 215. The control line groove in the groove insulation portion 207 in the control region 201 is filled with a conductive material. In this way, the conductive material in the control line groove in the groove insulation portion 207 in the control region 201 is electrically connected with the gate conductive layer 211 in the first gate 216, to form the control line 219 together.

Still referring to FIG. 4b, in the second gate groove provided in the second active region 215, a top surface of the gate conductive layer 211, a top surface of the gate barrier layer 210 and a top surface of the gate oxide layer 209 are lower than a notch of the second gate groove. In the second gate groove provided in the second active region 215, a gate insulation layer 220 is further provided above the gate conductive layer 211, the gate barrier layer 210 and the gate oxide layer 209, to insulate the gate conductive layer 211. For example, in the control line groove provided in the groove insulation portion 207 in the control region 201, a top surface of the conductive material filled in the control line groove is also lower than a notch of the control line groove, and the gate insulation layer 220 is also arranged above the conductive material in the control line groove, to insulate the conductive material in the control line groove.

Referring to FIG. 4c, the first source/drain region 217 and the second source/drain region 218 are respectively connected with a corresponding BL 205, and the BL 205 connected with the first source/drain region 217 and the BL 205 connected with the second source/drain region 218 are located on two sides of the control line 219.

It should be noted that the first source/drain region 217 and the second source/drain region 218 may be manufactured by ion implantation. For example, first, boron is doped in the second active region 215 to form a P-type semiconductor; second, phosphorus or arsenic is doped in the first source/drain region 217 and the second source/drain region 218 to form an N-type semiconductor. In this way, the first source/drain region 217 and the second source/drain region 218 are formed.

It should be noted that the first gate 216, the first source/drain region 217, and the second source/drain region 218 arranged in the second active region form an MOS field effect transistor.

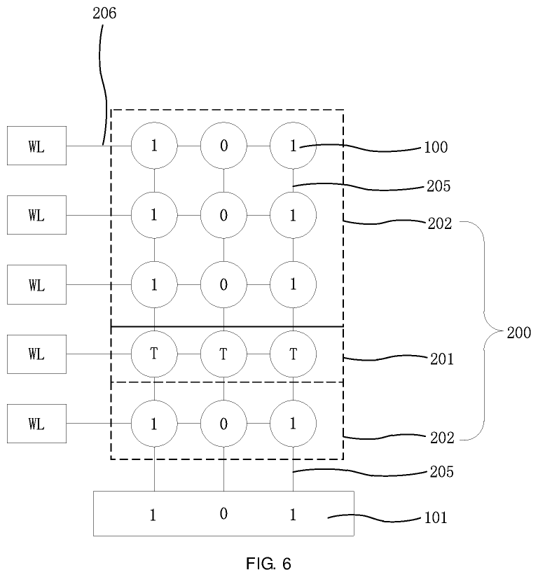

For illustrating the working principle of the memory in this embodiment, refer to FIG. 6. In this implementation, the memory includes three columns and four rows of memory cells 100. The memory cells 100 are the aforementioned capacitors 214. A row of three second active regions 215 is arranged between the third row and the fourth row. Obviously, all the memory cells 100 in the first row, all the memory cells 100 in the second row, and all the memory cells 100 in the third row constitute a storage region 202, the memory cells 100 in the fourth row constitute a storage region 202, and the three second active regions 215 in one row constitute a control region 201. The memory further includes three columns of BL groups, four rows of WLs 206, and one row of control lines 219. The memory cells 100 where each row of WLs is located are connected by four rows of WLs 206. Each column of BL 205 groups includes the BL 205 connecting the first row, the second row and the third row of this column, and the BL 205 connecting the fourth row of this column. The two BLs 205 in each column of BL 205 groups are respectively connected with the first source/drain region 217 and the second source/drain region 218 in the corresponding second active region 215. For example, when the memory cell 100 in the first column and the first row is to be read, the gate voltage of the second active region 215 in the first column may be controlled, to enable the two BLs 205 in the first column not connected. In this case, the memory cell 100 in the first column and the fourth row does not need to be loaded. Therefore, the loading time is shortened. When the memory cell 100 in the first column and the fourth row is to be read, the gate voltage of the second active region 215 in the first column may be controlled, to enable the two BLs 205 in the first column connected. In this case, the memory cell 100 in the first column of the fourth row may be loaded through all the memory cells 100 in the first column. In this way, when the number of read operations increases, the average storage speed of the memory is increased, and the performance of the memory is improved. In addition, the storage regions 202 can be reasonably grouped by controlling the positions of the second active regions 215, to enable frequently used memory cells 100 to be located in a same storage region 202. This can further accelerate the average storage speed of the memory and improve the performance of the memory.

In the memory provided in the embodiments of the present application, the control region 201 is provided on the substrate 200, two sides of the control region 201 are respectively provided with storage regions 202, the first contact regions 204 in each row of first active regions 203 in each storage region 202 are connected with a BL 205, and the first source/drain region 217 and the second source/drain region 218 of each second active region 215 in the control region 201 are respectively connected with the corresponding BLs 205 on both sides of the second active region 215. In this way, the voltage of the control line 219 can be controlled to control whether the BL 205 connected with the first source/drain region 217 and the BL 205 connected with the second source/drain region 218 are connected. Further, an effective length of the BL 205 is controlled during each read operation and write operation. That is, the number of memory cells 100 connected by the effective BL 205 is controlled during each read operation and write operation. In this way, the time of each read operation and write operation is controlled, so that the average storage speed of the memory is increased and the performance of the memory is improved.

Referring to FIG. 4d, a first conductive portion 221 is provided on the first source/drain region 217 in each second active region 215, and the first source/drain region 217 is connected with a corresponding BL 205 through the first conductive portion 221. The first conductive portion 221 can ensure a reliable connection between the first source/drain region 217 and the BL 205 and reduce the contact resistance.

Still referring to FIG. 4d, a second conductive portion 222 is provided on the second source/drain region 218 in each second active region 215, and the second source/drain region 218 is connected with a corresponding BL 205 through the second conductive portion 222. The second conductive portion 222 can ensure a reliable connection between the second source/drain region 218 and the BL 205 and reduce the contact resistance.

In some implementations, the first conductive portion 221 and the second conductive portion 222 are located on a same layer. In this way, the memory has a more compact structure with higher integration, which is convenient for manufacturing.

Referring to FIG. 4d, a third conductive portion 223 is provided on each first contact region 204. In each row of first active regions 203 in each storage region 202, third conductive portions on all first contact regions 204 are connected by one BL 205. The third conductive portion 223 can ensure a reliable connection between the first contact region 204 and the BL 205 and reduce the contact resistance.

In some implementations, the first conductive portion 221, the second conductive portion 222, and the third conductive portion 223 are located on a same layer. In this way, the memory has a more compact structure with higher integration, which is convenient for manufacturing.

In some implementations, the first gate 216 and the second gate 208 are located on a same layer. In this way, the memory has a more compact structure with higher integration, which is convenient for manufacturing.

In some implementations, multiple control regions 201 and multiple storage regions 202 are provided on the substrate 200, and the control regions 201 and the storage regions 202 are alternately arranged. For example, in some implementations, two control regions 201 and three storage regions 202 are provided on the substrate 200. The three storage regions 202 are arranged along the second direction, and one control region 201 is arranged between every two adjacent storage regions 202, so that the control regions 201 and the storage regions 202 are alternately arranged. The multiple control regions 201 and storage regions 202 on the substrate 200 can increase the storage speed of the memory and improve the storage performance.

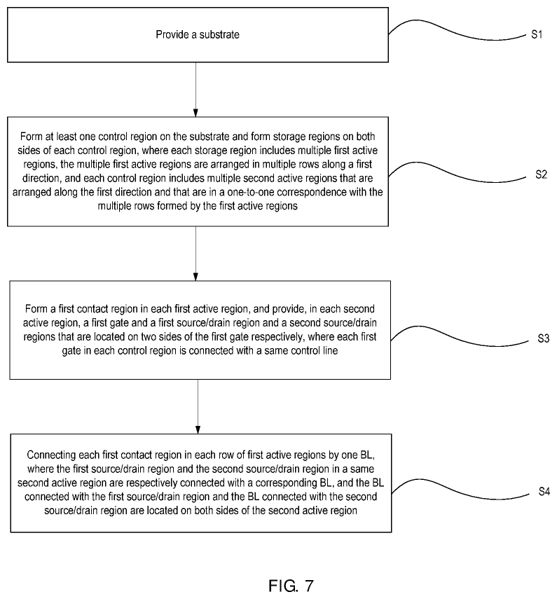

A second aspect of the embodiments further provides a manufacturing method of a memory, including the following steps shown in FIG. 7:

Step S1: Provide a substrate 200.

In the step S1, the material of the substrate 200 may be, for example, monocrystalline silicon, polycrystalline silicon, amorphous silicon, silicon-germanium compound, silicon-on-insulator, and other materials known to those skilled in the art.

Step S2: Form a control region 201 on the substrate 200 and form storage regions 202 on both sides of the control region 201, where each storage region 202 includes multiple first active regions 203, the multiple first active regions 203 are arranged in multiple rows along a first direction, and each control region 201 includes multiple second active regions 215 that are arranged along the first direction and that are in a one-to-one correspondence with the multiple rows formed by the first active regions 203.

Referring to FIG. 2a and FIG. 2b, forming the control region 201 and the storage regions 202 in the step S2 may include, for example:

Step S21: Provide a groove on the substrate 200. Specifically, for example, first, a patterned mask layer is formed on a top surface of the substrate 200 through a photolithography process; second, an etching process is performed on the substrate 200 by using the mask layer, to obtain the groove.

Step S22: Fill the groove with an insulation material to form a groove insulation portion 207. The insulation material may be, for example, silicon oxide or silicon nitride. When the groove is filled with the insulation material, planarization treatment may be performed on the substrate 200 on which the groove is provided, and the first active regions 203 and the second active regions 215 are effectively electrically isolated. The method for filling the groove with the insulation material is specifically as follows. First, a deposition process is performed to deposit an insulation layer on the substrate 200 on which the groove is provided; then, the insulation layer on the top surface of the substrate 200 is removed, and only the insulation material in the groove is kept. In this way, the groove insulation portion 207 is formed.

Certainly, after the groove is filled with the insulation material, high-temperature annealing treatment may be performed to reduce the pressure on the substrate.

Step S3: Form a first contact region 204 in each first active region 203, and provide, in each second active region 215, a first gate 216 and a first source/drain region 217 and a second source/drain region 218 that are located on two sides of the first gate 216 respectively, where all first gates 216 in the control region 201 are connected with each other to form a control line 219.

Referring to FIG. 3a and FIG. 3b, the step S3 may specifically include

Step S31: Perform ion implantation twice in the first active region 203 and the second active region 215, to form a first ion-doped layer located higher and a second ion-doped layer located lower in the first active region 203 and the second active region 215. The first ion-doped layer and the second ion-doped layer are formed as different types of semiconductors. For example, the first ion-doped layer is an n-type semiconductor, and the second ion-doped layer is a p-type semiconductor.

Step S32: Form a second gate groove in each second active region 215, where first ion-doped layers on both sides of the second gate groove respectively form the first source/drain region 217 and the second source/drain region 218, and form a control line groove in communication with a gate groove on the groove insulation portion 207 between two adjacent second active regions 215 in each control region 201. For example, the specific manufacturing process of this step may be as follows: First, a patterned mask layer is formed through the photolithography process on the top surface of the substrate 200 on which the first ion-doped layer and the second ion-doped layer are formed; second, etching process treatment is performed by using the mask layer on the substrate 200 on which the first ion-doped layer and the second ion-doped layer are formed. In this way, a first gate groove and the control line groove are obtained.

Step S33: Form the first gate 216 in the first gate groove in the second active region 215. The first gate 216 includes, for example, a gate oxide layer 209, a gate barrier layer 210, and a gate conductive layer 211. The deposition of conductive materials in the control line groove may specifically include, for example: First, the gate oxide layer 209 is deposited through a deposition process on the substrate 200 provided with the first gate groove and the control line groove, and the gate oxide layer 209 on the top surface of the substrate 200 and the gate oxide layer 209 in the control line groove are removed, but only the gate oxide layer 209 in the first gate groove is kept; second, the gate barrier layer 210 is further deposited through the deposition process, and the gate barrier layer 210 on the top surface of the substrate 200 and the gate barrier layer 210 in the control line groove are removed, but only the gate barrier layer 210 in the first gate groove is kept; then, the gate conductive layer 211 is further deposited through the deposition process, and the gate conductive layer 211 on the top surface of the substrate 200 is removed, but only the gate conductive layer 211 in the gate groove and the control line groove is kept.

Step S34: Provide a gate insulation layer 220 in the first gate groove, for example, which may specifically include: First, an etching-back process is used to enable a top surface of the gate oxide layer 209, a top surface of the gate barrier layer 210, and a top surface of the gate conductive layer 211 to be lower than a notch of the first gate groove, where the top surface of the gate oxide layer 209, the top surface of the gate barrier layer 210, and the top surface of the gate conductive layer 211 are at different heights due to different etching selectivities; second, the gate insulation layer 220 is deposited through the deposition process, and the gate insulation layer 220 on the top surface of the substrate 200 is removed, but only the gate insulation layer 220 in the gate groove and the control line groove is kept. The gate insulation layer 220 is used to effectively insulate the gate conductive layer 211.

It should be explained that the specific steps of the step S3 are only examples. In the actual manufacturing process, the steps may be optimized. If the steps are optimized only by changing the pattern of the mask layer to form the control line groove and deposit the gate conductive layer 211 and the gate insulation layer 220 in the control line groove in different steps, the optimization falls within the protection scope of the embodiments. For example, in the specific steps of the step S3, the step S32 includes forming the first gate groove in each second active region 215, and excludes forming the control line groove in communication with the first gate groove on the groove insulation portions 207 between two adjacent second active regions 215 in each control region 201; the step S33 includes forming the first gate 216 in the first gate groove, and excludes the deposition of the conductive material in the control line groove. In addition, the specific steps of the step S3 may further include: step S35: form the control line groove in communication with the first gate groove on the groove insulation portions 207 between two adjacent second active regions 215 in each control region 201; and step S36: deposit the conductive material in the control line groove.

Step S4: Form a BL 205 connecting all first contact regions 204 in each row of first active regions 203, where the first source/drain region 217 and the second source/drain region 218 in a same second active region 215 are respectively connected with a corresponding BL 205, and the BL 205 connected with the first source/drain region 217 and the BL 205 connected with the second source/drain region 218 are located on both sides of the control line 219.

Refer to FIG. 4a, FIG. 4b, FIG. 4c, and FIG. 4d, the step S4 may specifically include:

Step S41: Form BLs 205 through photolithography, etching and deposition processes on the substrate 200 provided with the control line 219. In this case, in the multiple formed rows of BLs 205, each BL 205 is connected with all first contact regions 204 in the corresponding row, all the first contact regions 204 in the corresponding row include all first contact regions 204 in the corresponding row in all the storage regions 202. Each BL 205 is further connected with a first source/drain region 217 or a second source/drain region 218 in a corresponding second active region 215.

Step S42: Cut off the BL 205 through the photolithography and etching processes on the substrate 200 provided with the BL 205, where the cutoff position is the position where each BL 205 intersects the control line 219, that is, the BL 205 is cut off at a position of the BL 205 directly above the control line 219.

In some implementations, ion doping may be performed in the second active region 215 for a third time to improve the conductivity of the semiconductor and reduce the contact resistance.

Referring to FIG. 4b, in each second active region 215, the first conductive portion 221 is formed on the first source/drain region 217, and the first source/drain region 217 is connected with a corresponding BL 205 through the first conductive portion 221.

Specifically, for example, before the step S41 of the step S4, the method further includes:

First, provide a patterned mask layer on the substrate 200 provided with the control line 219, where the first source/drain region 217 is exposed through an opening provided on the mask layer.

Second, etch away an upper half of the first source/drain region 217 by using the mask layer, and then remove the mask layer.

Then, deposit a conductive layer through the deposition process, and remove the conductive layer on the surface of the substrate 200, but only keep the conductive layer in the first source/drain region 217, to form the first conductive portion 221.

Finally, perform the step S41 of the step S4. That is, the BL 205 is formed through the photolithography, etching, and deposition processes on the substrate 200 provided with the control line 219.

Referring to FIG. 4b, in each second active region 215, the second conductive portion 222 is formed on the second source/drain region 218, and the second source/drain region 218 is connected with the corresponding BL 205 through the second conductive portion 222.

Specifically, for example, before the step S41 of the step S4, the method further includes:

First, provide a patterned mask layer on the substrate 200 provided with the control line 219, where the second source/drain region 218 is exposed through an opening provided on the mask layer.

Second, etch away an upper half of the second source/drain region 218 by using the mask layer, and then remove the mask layer.

Then, deposit a conductive layer through the deposition process, and remove the conductive layer on the surface of the substrate 200, but only keep the conductive layer in the second source/drain region 218, to form the second conductive portion 222.

Finally, perform the step S41 of the step S4. That is, the BL 205 is formed through the photolithography, etching, and deposition processes on the substrate 200 provided with the control line 219.

Referring to FIG. 4b, the third conductive portion 223 is formed on the first contact region 204. In each row of first active regions 203 in each storage region 202, the third conductive portions 223 on all the first contact regions 204 are connected by one BL 205. The third conductive portion 223 can reduce the contact resistance between the first contact region 204 and the BL 205.

For example, a specific manufacturing process may be as follows:

First, provide a patterned mask layer on the substrate 200 provided with the control line 219, where the first contact region 204 is exposed through an opening provided on the mask layer.

Second, etch away an upper half of the first contact region 204 by using the mask layer, and then remove the mask layer.

Then, deposit a conductive layer through the deposition process, and remove the conductive layer on the surface of the substrate 200, but only keep the conductive layer in the first contact region 204, to form the third conductive portion 223.

Finally, perform the step S41 of the step S4. That is, the BL 205 is formed through the photolithography, etching, and deposition processes on the substrate 200 provided with the control line 219.

Referring to FIG. 4b, in some implementations, the first conductive portion, the second conductive portion 222, and the third conductive portion 223 may be formed in a same process step. That is, in this implementation, the manufacturing process may be, for example:

First, provide a patterned mask layer on the substrate 200 provided with the control line 219, where the first source/drain region 217, the second source/drain region 218, and the first contact region 204 are all exposed through the opening provided on the mask layer.

Second, etch away an upper half of the first source/drain region 217, an upper half of the second source/drain region 218, and an upper half of the first contact region 204, and then remove the mask layer.

Then, deposit a conductive layer through the deposition process, and remove the conductive layer on the surface of the substrate 200, but only keep the conductive layer in the first source/drain region 217, the conductive layer in the second source/drain region 218, and the conductive layer in the first contact region 204, to form the first conductive portion 221, the second conductive portion 222, and the third conductive portion 223.

Finally, perform the step S41 of the step S4. That is, the BL 205 is formed through the photolithography, etching, and deposition processes on the substrate 200 provided with the control line 219.

Referring to FIG. 3a, in the memory manufactured by using the manufacturing method of a memory in the embodiments, the multiple first active regions 203 in each storage region 202 are arranged in multiple columns along the second direction; in any two adjacent rows of first active regions 203, columns of all first active regions 203 in one row and columns of all first active regions 203 in the other row are alternately arranged; each first active region 203 in a same column intersects two WLs 206; in any two adjacent columns of first active regions 203, ends of the first active regions in one column and ends of the first active regions in the other column that are close to each other intersect a same WL 206; each first active region 203 in a same column is provided with two second gates 208, and the two second gates 208 are respectively connected with the two WLs 206 alternately arranged in the first active region 203. The first contact region 204 in each first active region 203 is located between the two second gates in the first active region 203, that is, the first contact region 204 in each first active region 203 is located between the two WLs 206 alternately arranged in the first active region 203.

It should be noted that the first gate 216 and the second gate 208 may be provided in a same process step to simplify the manufacturing process. Referring to FIG. 3a and FIG. 3b, specifically, for example, the step S32 of the step S3 may further include: forming two first gate grooves in each first active region 203, where the first ion-doped layer between the two first gate grooves forms the first contact region 204. The process of forming the first gate groove in the first active region 203 may be the same as that of forming the second gate groove in the second active region 215, and corresponding improvements are only made to the pattern of the mask. The step S33 may further include forming the second gate 208 in the first gate groove in the first active region 203. The manufacturing process of the second gate 208 is exactly the same as that of the first gate 216, and corresponding changes are only made to the pattern of the mask in the manufacturing process.

In the foregoing implementations, two first gate grooves are provided on the first active region 203, and a first ion implantation layer on a side of each first gate groove away from the other first gate groove is the second contact region 212.

In some implementations, in the memory manufactured by using the manufacturing method of a memory in the embodiments, each first active region 203 further includes a second contact region 212 provided on a side of each second gate 208 away from the first contact region 204, and each second contact region 212 is connected with a corresponding charge storage element. The charge storage element is, for example, a capacitor 214.

Referring to FIG. 5a, FIG. 5b and FIG. 5c, manufacturing the capacitor 214 may be specifically as follows:

First, provide a fourth conductive portion 213 above the second contact region 212 through the photolithography, etching, and deposition processes.

Second, form the capacitor 214 above the fourth conductive portion 213 through the photolithography, etching, and deposition processes.

Referring to FIG. 5b and FIG. 5c, in the memory and the memory manufactured by using the manufacturing method thereof in the embodiments, the capacitor 214 is formed only above the second contact region 212 in the first active region 203 in the storage region 202, and no capacitor 214 is provided above the second active region 215 in the control region 201, and only the insulation layer is correspondingly deposited in the control region 201.

In some implementations, multiple control regions 201 and multiple storage regions 202 are formed on the substrate 200, and the control regions 201 and the storage regions 202 are alternately arranged. The multiple control regions 201 and storage regions 202 on the substrate 200 can increase the storage speed of the memory and improve the storage performance. It should be noted that forming multiple control regions 201 and multiple storage regions 202 on the substrate 200, for example, forming one control region 201 and two storage regions 202, or forming two control regions 201 and three storage regions 202 uses the same manufacturing steps. In this way, the manufactured memory has an increased speed, and the performance is improved, while no additional manufacturing steps are needed.

In the manufacturing method of a memory in the embodiments, the first active region 203 and the second active region 215 may be formed in a same process step, the first contact region 204, the second contact region 212, the first source/drain region 217 and the second source/drain region 218 may be formed in a same process step, the first gate 216 and the second gate 208 may be formed in a same process step, the WL 206 and the control line 219 may be formed in a same process step, and the BLs 205 may be formed in a same process step. In this way, no new process step is needed in the entire manufacturing process of a memory. Moreover, compared with the first active region 203, the second active region 215 is formed by making corresponding changes to the structure in the vicinity of the second gate 208. Therefore, only the opening position of the mask needs to be modified accordingly in the process, and the layout pattern of this mask is similar to that in the related technology. Therefore, the manufacturing method of a memory in the embodiments has a simple process and is easy to implement.

Each embodiment or implementation in the specification is described in a progressive manner. Each embodiment focuses on the differences from other embodiments, and the same and similar parts between the embodiments may refer to each other.

In the descriptions of this specification, a description with reference to the term “one implementation”, “some implementations”, “an exemplary implementation”, “an example”, “a specific example”, “some examples”, or the like means that a specific feature, structure, material, or characteristic described in combination with the implementation(s) or example(s) is included in at least one implementation or example of the present application. In this specification, the schematic expression of the above terms does not necessarily refer to the same implementation or example. Moreover, the described specific feature, structure, material or characteristic may be combined in an appropriate manner in any one or more implementations or examples.

Finally, it should be noted that the above embodiments are merely used to explain the technical solutions of the present application, but are not intended to limit the present application. Although the present application is described in detail with reference to the foregoing embodiments, those of ordinary skill in the art should understand that they can still modify the technical solutions described in the foregoing embodiments, or make equivalent substitutions on some or all technical features therein. These modifications or substitutions do not make the essence of the corresponding technical solutions deviate from the scope of the technical solutions of the embodiments of the present application.

1. A memory, comprising a substrate, wherein the substrate is provided with a control region, and two sides of the control region are respectively provided with storage regions;
each of the storage regions comprises multiple first active regions, the multiple first active regions are arranged in multiple rows along a first direction, each of the first active regions is provided with a first contact region, and all the first contact regions in each row of the first active regions are connected by a bit line;
the control region comprises multiple second active regions that are arranged along the first direction and that are in a one-to-one correspondence with the multiple rows formed by the first active regions;
each of the second active regions is provided with a first gate and a first source/drain region and a second source/drain region that are located on two sides of the first gate, and all the first gates in the control region are connected with each other to form a control line; and
the first source/drain region and the second source/drain region in a same second active region are respectively connected with a corresponding bit line, and the bit line connected with the first source/drain region and the bit line connected with the second source/drain region are located on two sides of the control line.

2. The memory according to claim 1, wherein a first conductive portion is provided on the first source/drain region in each of the second active regions, and the first source/drain region is connected with the corresponding bit line through the first conductive portion.

3. The memory according to claim 2, wherein a second conductive portion is provided on the second source/drain region in each of the second active regions, and the second source/drain region is connected with the corresponding bit line through the second conductive portion.

4. (canceled)

5. The memory according to claim 3, wherein a third conductive portion is provided on each of the first contact regions; and
in each row of the first active regions in each of the storage regions, the third conductive portion on each of the first contact regions is connected to one of the bit lines.

6. The memory according to claim 5, wherein the first conductive portion, the second conductive portion, and the third conductive portion are located on a same layer.

7. The memory according to claim 1, wherein the multiple first active regions in each of the storage regions are arranged in multiple columns along a second direction; in any two adjacent rows of the first active regions, columns of all the first active regions in one row and columns of all the first active regions in the other row are alternately arranged; each of the first active regions in a same column intersects two same word lines; in any two adjacent columns of the first active regions, ends of the first active regions in one column and ends of the first active regions in the other column that are close to each other intersect a same word line, wherein the second direction is perpendicular to the first direction; and
each of the first active regions in a same column is provided with two second gates, and the two second gates are respectively connected with two word lines alternately arranged in the first active region.

8. The memory according to claim 7, wherein the first contact region in each of the first active regions is located between the two second gates.

9. The memory according to claim 7, wherein the first gate and the second gate are located on a same layer.

10. The memory according to claim 7, wherein each of the first active regions further comprises a second contact region provided on a side of each of the second gates away from the first contact region, and each of the second contact regions is connected with a corresponding charge storage element.

11. The memory according to claim 1, wherein multiple control regions and multiple storage regions are provided on the substrate, and the control regions and the storage regions are alternately arranged.

12. A manufacturing method of a memory, comprising:
providing a substrate;
forming a control region on the substrate and forming storage regions on both sides of the control region, wherein each of the storage regions comprises multiple first active regions, the multiple first active regions are arranged in multiple rows along a first direction, and the control region comprises multiple second active regions that are arranged along the first direction and that are in a one-to-one correspondence with the multiple rows formed by the first active regions;
forming a first contact region in each of the first active regions, and providing, in each of the second active regions, a first gate and a first source/drain region and a second source/drain region that are located on two sides of the first gate, wherein all the first gates in the control region are connected with each other to form a control line; and
forming a bit line connecting all first contact regions in each row of the first active regions, wherein the first source/drain region and the second source/drain region in a same second active region are respectively connected with a corresponding bit line, and the bit line connected with the first source/drain region and the bit line connected with the second source/drain region are located on two sides of the control line.

13. The manufacturing method of the memory according to claim 12, wherein a first conductive portion is formed on the first source/drain region in each of the second active regions, and the first source/drain region is connected with the corresponding bit line through the first conductive portion.

14. The manufacturing method of the memory according to claim 13, wherein a second conductive portion is formed on the second source/drain region in each of the second active regions, and the second source/drain region is connected with the corresponding bit line through the second conductive portion.

15. (canceled)

16. The manufacturing method of the memory according to claim 14, wherein a third conductive portion is formed on each of the first contact regions; and
in each row of the first active regions in each of the storage regions, the third conductive portion on each of the first contact regions is connected with one of the bit lines.

17. The manufacturing method of the memory according to claim 16, wherein the first conductive portion, the second conductive portion, and the third conductive portion are formed in a same process step.

18. The manufacturing method of the memory according to claim 12, wherein the multiple first active regions in each of the storage regions are arranged in multiple columns along a second direction; in any two adjacent rows of the first active regions, columns of all the first active regions in one row and columns of all the first active regions in the other row are alternately arranged; each of the first active regions in a same column intersects two same word lines; in any two adjacent columns of the first active regions, ends of the first active regions in one column and ends of the first active regions in the other column that are close to each other are connected with a same word line; and
each of the first active regions in a same column is provided with two second gates, and the two second gates are respectively connected with two word lines alternately arranged in the first active region.

19. The manufacturing method of the memory according to claim 18, wherein the first contact region in each of the first active regions is located between the two second gates.

20. The manufacturing method of the memory according to claim 18, wherein the first gate and the second gate are provided in a same process step.

21. The manufacturing method of the memory according to claim 18, wherein a second contact region is further formed in each of the first active regions on a side of each of the second gates away from the first contact region, and each of the second contact regions is connected with a corresponding charge storage element.

22. The manufacturing method of the memory according to claim 12, wherein multiple control regions and multiple storage regions are formed on the substrate, and the control regions and the storage regions are alternately arranged.
